(19) United States
(12) Patent Application Publication
(10) Pub. No.: US 2026/0239727 A1
(43) Pub. Date: Aug. 13, 2026

(54) DIRECT BACKSIDE CONTACT WITHOUT PLACEHOLDER

(71) Applicant: INTERNATIONAL BUSINESS MACHINES CORPORATION, Armonk, NY (US)

(72) Inventors: SHRAVAN KUMAR MATHAM, Albany, NY (US); Ruilong Xie, Niskayuna, NY (US); Mahender Kumar, Clifton Park, NY (US); Ravikumar Ramachandran, Pleasantville, NY (US); Kisik Choi, Watervliet, NY (US); Julien Frougier, Albany, NY (US); Shogo Mochizuki, Mechanicville, NY (US)

(21) Appl. No.: 19/048,252

(22) Filed: Feb. 7, 2025

(51) Int. Cl. H10D 84/83; H10D 30/00; H10D 62/10; H10D 64/01; H10D 64/23; H10D 64/27; H10D 84/01

(52) U.S. Cl. CPC H10D 84/832; H10D 30/502; H10D 62/116; H10D 64/017; H10D 64/258; H10D 64/518; H10D 84/0151; H10D 84/83138

(57) ABSTRACT

A semiconductor structure including a nanosheet stack comprising a series of channel nanosheets, dielectric nanosheet layers arranged directly beneath the series of channel nanosheets, and semiconductor layers between and physically separating the dielectric nanosheet layers from one another.

### BACKGROUND

The present invention generally relates to semiconductor structures, and more particularly to nanosheet transistor structures having direct backside contact without requiring a placeholder fabrication scheme.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a nanosheet stack comprising a series of channel nanosheets, dielectric nanosheet layers arranged directly beneath the series of channel nanosheets, and semiconductor layers between and physically separating the dielectric nanosheet layers from one another.

According to another embodiment of the present invention, a semiconductor structure is provided. The semiconductor structure may include a nanosheet stack comprising a series of channel nanosheets, at least two dielectric nanosheet layers arranged directly beneath the series of channel nanosheets, and at least one semiconductor layer between and physically separating the at least two dielectric nanosheet layers from one another.

According to another embodiment of the present invention, a semiconductor structure is provided. The semiconductor structure may include a first nanosheet stack comprising a first series of channel nanosheets, at least three first dielectric nanosheet layers arranged directly beneath the first series of channel nanosheets, at least one first semiconductor layer between and physically separating two of the at least three first dielectric nanosheet layers from one another, and a gate structure between and physically separating two of the at least three first dielectric nanosheet layers from one another.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after patterning the nanosheet layers into nanosheet fins and forming shallow trench isolation regions according to an exemplary embodiment;

FIGS. 8, 9, and 10 are cross-sectional views of the semiconductor structure after forming sacrificial gates according to an exemplary embodiment;

FIGS. 11, 12, and 13 are cross-sectional views of the semiconductor structure after forming sidewall spacers, removing portions of the nanosheet fins to create individual nanosheet stacks and source drain openings according to an exemplary embodiment;

FIGS. 14, 15, and 16 are cross-sectional views of the semiconductor structure after removing the second sacrificial nanosheets and forming dielectric nanosheet layers according to an exemplary embodiment;

FIGS. 17, 18, and 19 are cross-sectional views of the semiconductor structure after forming inner spacers according to an exemplary embodiment;

FIGS. 20, 21, and 22 are cross-sectional views of the semiconductor structure after source drain regions and a dielectric layer according to an exemplary embodiment;

FIGS. 23, 24, and 25 are cross-sectional views of the semiconductor structure after selectively removing the sacrificial gates and the first sacrificial nanosheets, and forming gate structures according to an exemplary embodiment;

FIGS. 26, 27, and 28 are cross-sectional views of the semiconductor structure after forming middle-of-line, back-end-of-line, and attaching a carrier wafer according to an exemplary embodiment;

FIGS. 29, 30, and 31 are cross-sectional views of the semiconductor structure after flipping the assembly and recessing the substrate according to an exemplary embodiment;

FIGS. 32, 33, and 34 are cross-sectional views of the semiconductor structure after removing and recessing remaining portions of the substrate according to an exemplary embodiment;

FIGS. 35, 36, and 37 are cross-sectional views of the semiconductor structure after forming a backside dielectric layer according to an exemplary embodiment; and

FIGS. 38, 39, and 40 are cross-sectional views of the semiconductor structure after forming backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional placeholder fabrication techniques run the risk of causing damage to the gate hard mask, resulting spacer loss and epi nodules. The placeholder-based backside contact also involves high aspect ratio patterning, which increases risk of gate bending or collapse. Therefore, it is desired to form backside contacts without need of creating deep placeholders under source drain regions.

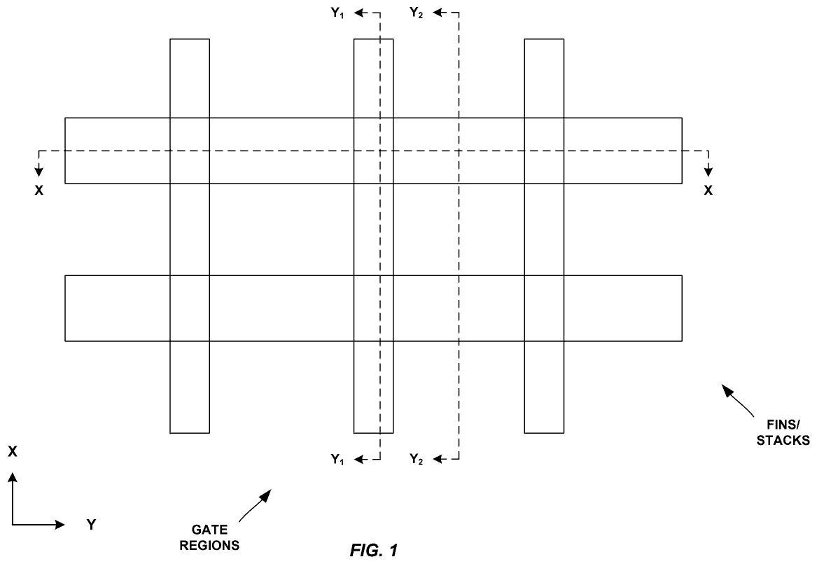

The present invention generally relates to semiconductor structures, and more particularly to nanosheet transistor structures having direct backside contacts without requiring a placeholder fabrication scheme. More specifically, the nanosheet transistor structures and associated method disclosed herein enable a novel nanosheet stack and associated nanosheet dielectric layers to electrically isolate the direct backside contacts from the gate. Further, the associated nanosheet dielectric layers prevent shorting between the direct backside contacts and the gate. Exemplary embodiments of nanosheet transistor structures having direct backside contacts insulated from the gate by nanosheet dielectric layers are described in detail below by referring to the accompanying drawings in FIGS. 1 to 40. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, and gate regions situated perpendicular to the fins/stacks. FIG. 1-40 represent cross section views oriented as indicated in FIG. 1

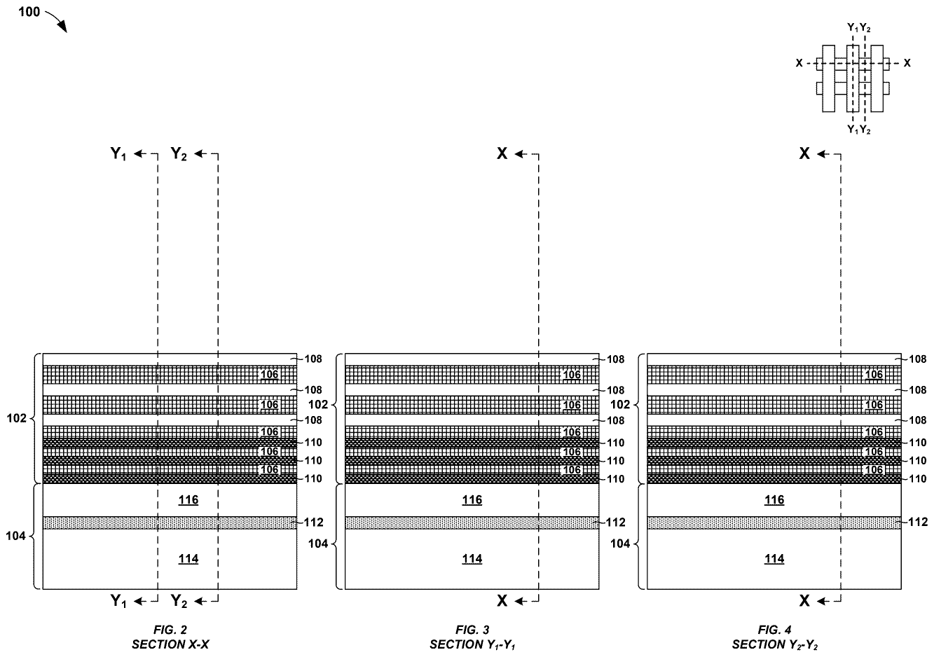

Referring now to FIGS. 2, 3, and 4, a structure 100 is shown during an intermediate step of a method of fabricating nanosheet transistor structures according to an embodiment of the invention. FIG. 2 depicts a cross-sectional view of the structure 100 taken along line X-X, FIG. 3 depicts a cross-sectional view of the structure 100 taken along line Y₁-Y₁, and FIG. 4 depicts a cross-sectional view of the structure 100 taken along line Y₂-Y₂.

The structure 100 illustrated in FIG. 2-4 includes nanosheet layers 102 formed on a substrate 104. For purposes of orientation, the substrate 104 is herein referred to as being on a “backside” of the structure 100 and the nanosheet layers 102 are herein referred to as being on a “frontside” of the structure 100. Further, certain features may be described herein as having a relative position with respect to the frontside or backside of the structure 100.

The nanosheet layers 102 include an alternating series of first silicon germanium (SiGe) sacrificial nanosheets 106 (hereinafter “first sacrificial nanosheets 106”), silicon (Si) channel nanosheets 108 (hereinafter “channel nanosheets 108”), and second silicon germanium (SiGe) sacrificial nanosheets 110 (hereinafter “second sacrificial nanosheets 110”), as illustrated. Specifically, for example, a top half of the nanosheet layers 102 include the channel nanosheets 108 separated from one another by the first sacrificial nanosheets 106, and a bottom half of the nanosheet layers 102 include the second sacrificial nanosheets 110 separated from one another by the first sacrificial nanosheets 106. According to the disclosed embodiments, the top layer of the nanosheet layers 102 is one of the channel nanosheets 108, and the bottom layer of the nanosheet layers 102 is one of the second sacrificial nanosheets 110, as illustrated

According to embodiments of the present invention, the nanosheet layers 102 include three of the channel nanosheets 108 and three of the second sacrificial nanosheets 110. Although only a discrete number of individual layers are shown, the nanosheet layers 102 may include any number of individual layers in any number of combinations. For example, according to an embodiment, the nanosheet layers 102 include more than three of the channel nanosheets 108 and less than three of the second sacrificial nanosheets 110. In another embodiment, the nanosheet layers 102 includes at least two of the second sacrificial nanosheets 110 arranged in the bottom half as described above.

According to embodiments of the present disclosure, the first sacrificial nanosheets 106 have a different germanium concentration than the second sacrificial nanosheets 110. In at least one embodiment, the second sacrificial nanosheets 110 have a higher germanium concentration than the first sacrificial nanosheets 106. More specifically, for example, the second sacrificial nanosheets 110 may have a germanium concentration ranging from about 45 to about 70 percent, while the first sacrificial nanosheets 106 may have a germanium concentration ranging from about 15 to about 40 percent. In all cases, the different germanium concentrations are designed to allow for each of the first sacrificial nanosheets 106 and the second sacrificial nanosheets 110 to be etched selective to one another. As such, other germanium concentrations are explicitly contemplated.

According to embodiments of the present disclosure, individual layers in the bottom half of the nanosheet layers 102 have a different thickness than the individual layers in the top half of the nanosheet layers 102. In at least one embodiment, a thickness of each of the first sacrificial nanosheets 106 (in the bottom half) and the second sacrificial nanosheets 110 is less than a thickness of each of the first sacrificial nanosheets 106 (in the top half) and the channel nanosheets 108. More specifically, for example, each of the second sacrificial nanosheets 110 and the first sacrificial nanosheets 106 (in the bottom half) have a thickness of approximately 5 nm. Closely controlling thickness of the layers in the bottom half during formations helps avoid defects.

In one or more embodiments, the nanosheet layers 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet layers 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may be a layered semiconductor such as a silicon-on-insulator or SiGe-on-insulator, where an etch stop layer 112 separates a base substrate 114 from a top semiconductor layer 116. Unlike conventional layered semiconductor substrates, the etch stop layer 112 of the substrate 104 may include any material which affects the desired etch selectivity during subsequent processing. For example, the etch stop layer 112 may be a conventional buried oxide layer, or it may be a silicon germanium layer with a specific germanium concentration. In practice, the etch stop layer 112 will function as an etch stop layer and can be composed of any material which supports that function. For example, according to an embodiment, the etch stop layer 112 is made from silicon germanium having a different germanium concentration than other layers in the structure 100.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, both the etch stop layer 112 and the base substrate 114 are sacrificial and will not remain in the final structure. According to the disclosed embodiments, a thickness of the top semiconductor layer 116 is purposely reduced, for example, less than 15 nm, in order to ensure easy removal of the top semiconductor layer 116 in subsequent steps.

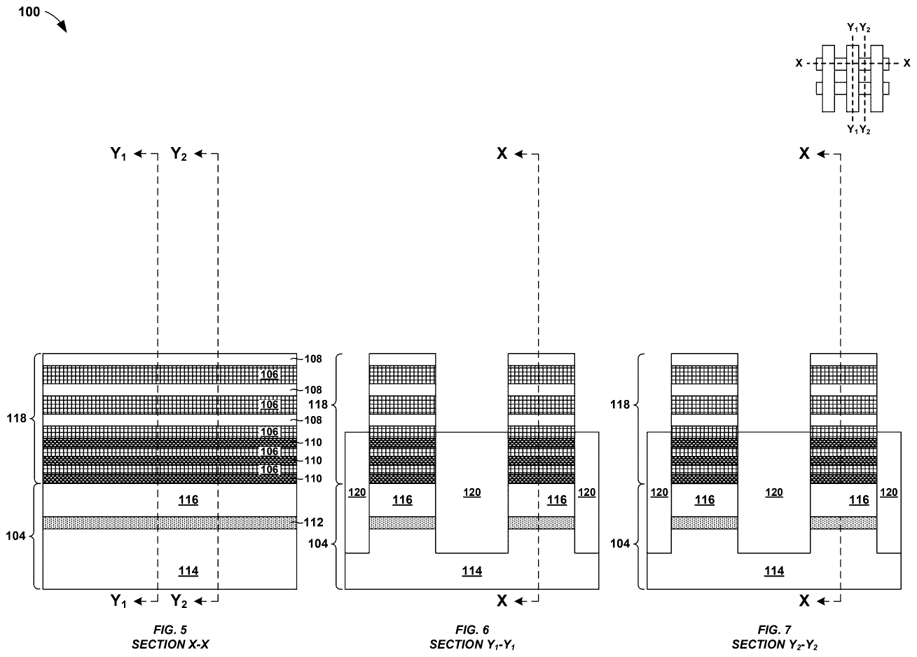

Referring now to FIGS. 5, 6, and 7, the structure 100 is shown after patterning the nanosheet layers 102 into nanosheet fins 118 and forming shallow trench isolation regions 120 according to an embodiment of the invention. FIG. 5 depicts a cross-sectional view of the structure 100 taken along line X-X, FIG. 6 depicts a cross-sectional view of the structure 100 taken along line Y₁-Y₁, and FIG. 7 depicts a cross-sectional view of the structure 100 taken along line Y₂-Y₂.

Known processing techniques have been applied to pattern the nanosheet layers 102 and form the nanosheet fins 118, as shown. For example, the known processing techniques can include the formation of hard masks (not shown) over the topmost layer of the nanosheet layers 102. The hard masks can be formed by first depositing the hard mask material (for example silicon nitride) onto the topmost layer of the nanosheet layers 102 using, for example, chemical vapor deposition (CVD), plasma enhanced CVD (PECVD) or any suitable technique for dielectric deposition that does not induce a physical or chemical change to the topmost layer of the nanosheet layers 102. According to an exemplary embodiment, the hard mask material is deposited onto the topmost layer of the nanosheet layers 102 and then patterned into a plurality of the individual hard masks. Patterning the hard mask is commensurate with a desired footprint and location of subsequently formed nanosheet fins 118 shown in the figures, and which will subsequently be used to form the channel regions of semiconductor devices disclosed herein. According to an exemplary embodiment, RIE is used to transfer the hard mask pattern into the nanosheet layers 102, and into the substrate 104, as shown. The remaining portions of the nanosheet layers 102 are hereafter referred to as the nanosheet fins 118.

Next, shallow trench isolation regions 120 (hereinafter “STI regions 120”) are formed according to known techniques. The STI regions 120 are formed at the bottom of trenches in the substrate 104 formed during patterning of the nanosheet layers 102 into the nanosheet fins 118, as illustrated. Specifically, a dielectric material is deposited at the bottom of trenches in the substrate 104 to isolate adjacent devices from one another according to known techniques. The STI regions 120 may be formed from any appropriate dielectric material including, for example, silicon oxide (SiOₓ) or silicon nitride (SiₓN_{y}).

Specific to the disclosed embodiments, the STI regions 120 are formed such that they substantially cover or protect sidewalls of lower portions of the nanosheet fins 118, as illustrated. More specifically, top surface of the STI regions 120 are at least above a topmost surface of the second sacrificial nanosheets 110, as best illustrated in FIGS. 6 and 7.

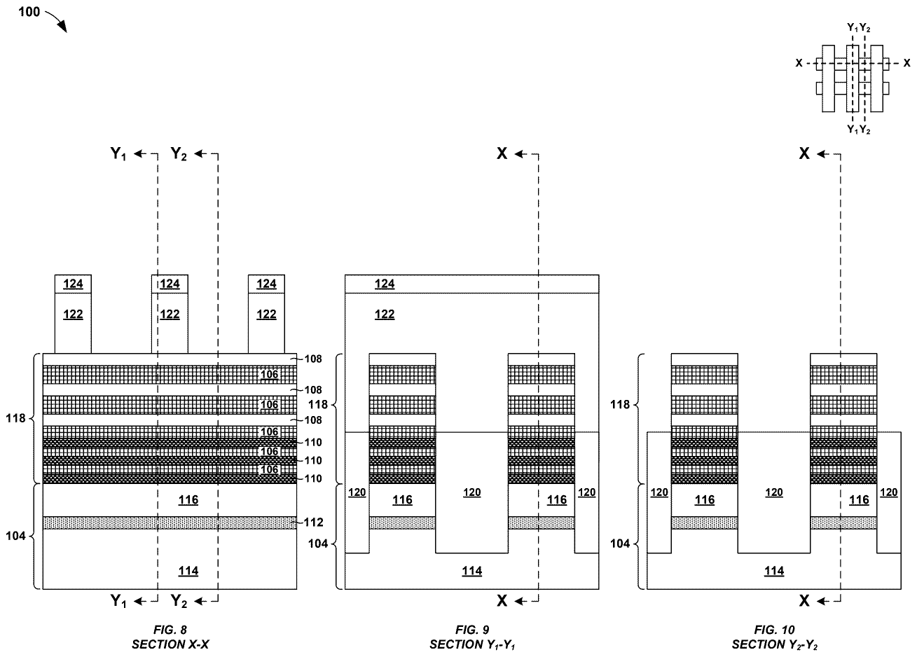

Referring now to FIGS. 8, 9, and 10, the structure 100 is shown after forming sacrificial gates 122 according to an embodiment of the invention. FIG. 8 depicts a cross-sectional view of the structure 100 taken along line X-X, FIG. 9 depicts a cross-sectional view of the structure 100 taken along line Y₁-Y₁, and FIG. 10 depicts a cross-sectional view of the structure 100 taken along line Y₂-Y₂.

First, a sacrificial gate dielectric is deposited directly on exposed surfaces of the structure 100 according to known techniques. Specifically, for example, a relatively thin layer of silicon oxide (SiO2) is first conformally deposited over and around the nanosheet fins 118.

Next, a sacrificial gate material is blanket deposited over and around the nanosheet fins 118 according to known techniques. Specifically, for example, a relatively thick layer of amorphous silicon is blanket deposited directly on the sacrificial gate dielectric. In this manner, both the sacrificial gate dielectric and the sacrificial gate material completely cover the nanosheet fins 118.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a gate hard mask 124 is formed over the structure 100. The gate hard mask 124 defines gate regions of individual devices. According to an exemplary embodiment, a mask material is deposited onto the sacrificial gate material and then patterned into a plurality of individual gate hard masks 124. Next, the pattern created by the individual gate hard masks 124 is transferred into the sacrificial gate dielectric and the sacrificial gate material. Specifically, portions of sacrificial gate dielectric and the sacrificial gate material are anisotropically etched or removed selective to the individual gate hard masks 124 to form the sacrificial gates 122, as illustrated. According to an embodiment, a silicon RIE process is used to selectively remove the portions of the sacrificial gate dielectric and the sacrificial gate material.

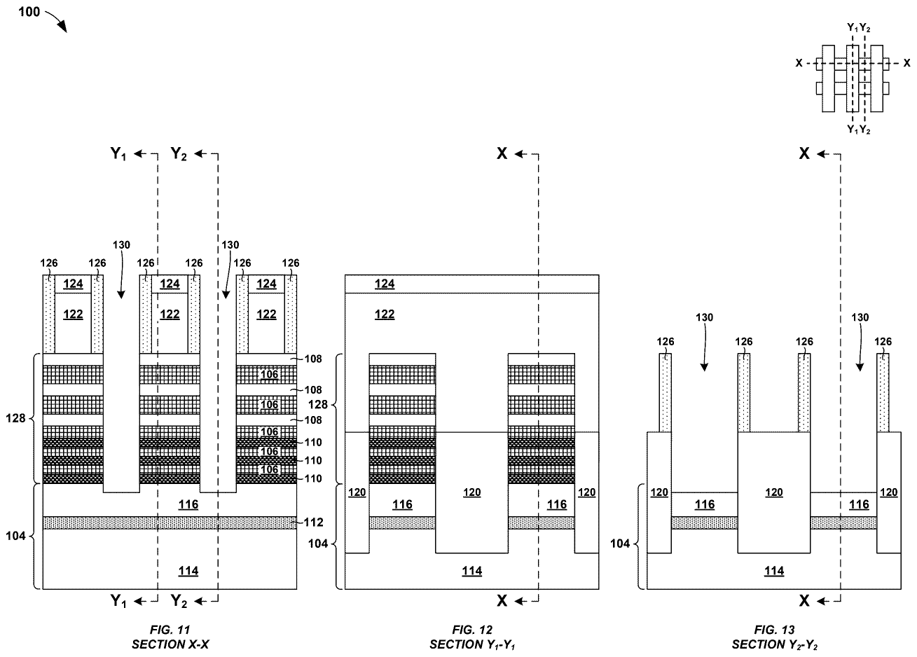

Referring now to FIGS. 11, 12, and 13, the structure 100 is shown after forming sidewall spacers 126, removing portions of the nanosheet fins 118 to create individual nanosheet stacks 128 and source drain openings 130 according to an embodiment of the invention. FIG. 11 depicts a cross-sectional view of the structure 100 taken along line X-X, FIG. 12 depicts a cross-sectional view of the structure 100 taken along line Y₁-Y₁, and FIG. 13 depicts a cross-sectional view of the structure 100 taken along line Y₂-Y₂.

The sidewall spacers 126 are formed by first depositing a conformal layer of dielectric material on top of the structure 100 according to known techniques. Specifically, the layer of dielectric material may be deposited directly on sidewalls of the sacrificial gates 122, sidewalls of the individual gate hard masks 124, and surfaces of the nanosheet fins 118 exposed between the sacrificial gates 122. In an embodiment, the layer of dielectric material can include, for example, SiN, SiBCN, SiOCN, SiC, SiOC, or any other combination of low-k materials. The term “low-k” as used throughout the present application denotes a dielectric material that has a dielectric constant of less than 4.0.

It may be preferable, in some cases, to fabricate the sidewall spacers 126 from a material having a substantially different etch rate than that of the surrounding materials to effect good etch selectivity during subsequent fabrication. In an embodiment, the layer of dielectric material may preferably include an oxide, for example, silicon oxide. The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the sacrificial gates 122 and on the sidewalls of the individual gate hard masks 124, as illustrated. For example, a reactive-ion-etching technique may be used to remove portions of the layer of dielectric material from directly above the nanosheet fins 118 and from top surfaces of the individual gate hard masks 124. The portions of the layer of dielectric material remaining along opposite sidewalls of the sacrificial gates 122 and the individual gate hard masks 124, form the sidewall spacers 126. Furthermore, the individual gate hard masks 124 and the sidewall spacers 126 should each include materials that would allow the individual gate hard masks 124 to be subsequently removed selective to the sidewall spacers 126. Here, it should also be noted that the sidewall spacers 126 depicted in the figures are for illustration purposes and generally can have a slightly different shape from those shown. For example, the sidewall spacers 126 can have rounded corners which may naturally form during the directional etching process as is known in the art.

The sidewall spacers 126 may have a lateral width substantially equal to the conformal thickness of the layer of dielectric material above. In an embodiment, the lateral width of the sidewall spacers 126 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the sidewall spacers 126 may have a lateral width ranging from about 5 nm to about 15 nm, and ranges there between. It is possible to adjust spacer width based on etch bias or loss of material during process to meet final technology target dimension. The sidewall spacers 126 help define active regions which may subsequently be transferred into underlying layers.

Next, the individual nanosheet stacks 128 and the source drain openings 130 are formed by removing portions of the nanosheet fins 118 according to known techniques. Specifically, the pattern created by the individual gate hard masks 124 and the sidewall spacers 126 is transferred into the nanosheet fins 118. In doing so, portions of the first sacrificial nanosheets 106, the channel nanosheets 108, the second sacrificial nanosheets 110, and the substrate 104 are removed, as illustrated.

In an embodiment, portions of the nanosheet fins 118 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until at least the topmost surface of the substrate 104 is exposed. In some embodiments, as illustrated, etching continues until the source drain openings 130 extend into the top semiconductor layer 116.

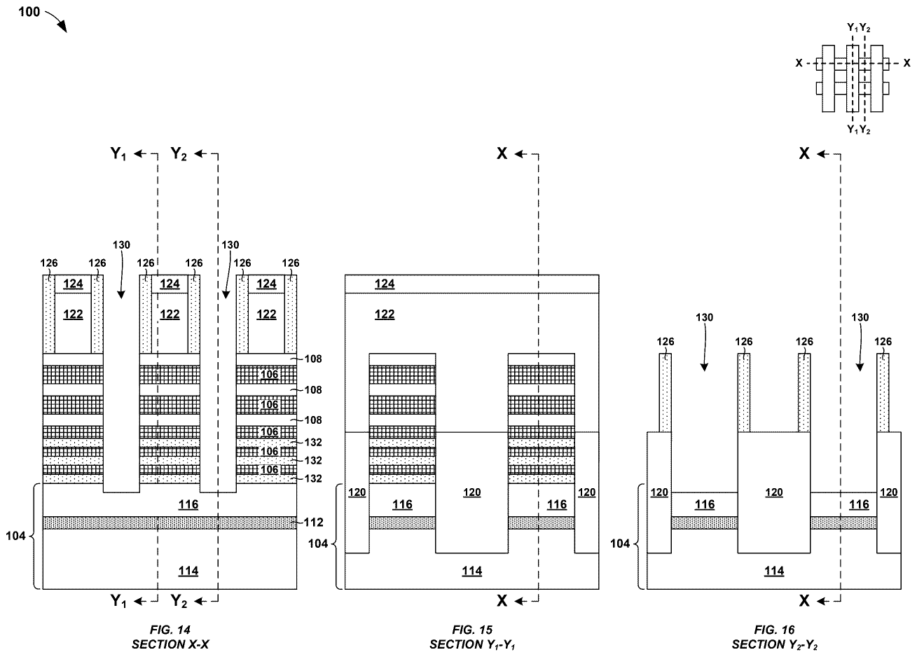

Referring now to FIGS. 14, 15, and 16, the structure 100 is shown after removing the second sacrificial nanosheets 110 and forming dielectric nanosheet layers 132 according to an embodiment of the invention. FIG. 14 depicts a cross-sectional view of the structure 100 taken along line X-X, FIG. 15 depicts a cross-sectional view of the structure 100 taken along line Y₁-Y₁, and FIG. 16 depicts a cross-sectional view of the structure 100 taken along line Y₂-Y₂.

The second sacrificial nanosheets 110 are selectively removed according to known techniques. Specifically, the second sacrificial nanosheets 110 are isotropically etched and removed selective to the first sacrificial nanosheets 106 and the channel nanosheets 108 according to known techniques. According to an embodiment, a selective etching process, such as vapor phase HCl dry etch, is used to selectively remove the second sacrificial nanosheets 110. The desired etch selectivity is made possible by the different concentrations of germanium. In this case, the layers with the relatively higher germanium concentration, for example the second sacrificial nanosheets 110, are removed selective to layers with the relatively lower germanium concentrations, for example the first sacrificial nanosheets 106 and the channel nanosheets 108.

Next, the dielectric nanosheet layers 132 are formed according to known techniques. Specifically, a dielectric material is blanket deposited on exposed surfaces of the structure 100 according to known techniques. Specifically, for example, a relatively thin layer of silicon nitride or silicon oxide is conformally deposited. In some embodiments, for example, the dielectric material may be composed of SiN, SiBCN, SiOCN, SiC, SiOC, or any other combination of low-k materials. After depositing, portions of the dielectric layer are removed from within the source drain openings 130 and portions of the dielectric layer remaining sandwiched between the first sacrificial nanosheets 106 form the dielectric nanosheet layers 132, as illustrated.

According to embodiments of the present disclosure, the dielectric nanosheet layers 132 substantially fill the spaces or openings created by removing the second sacrificial nanosheets 110, and will later function to isolate subsequently formed direct backside contacts from subsequently formed gate structures.

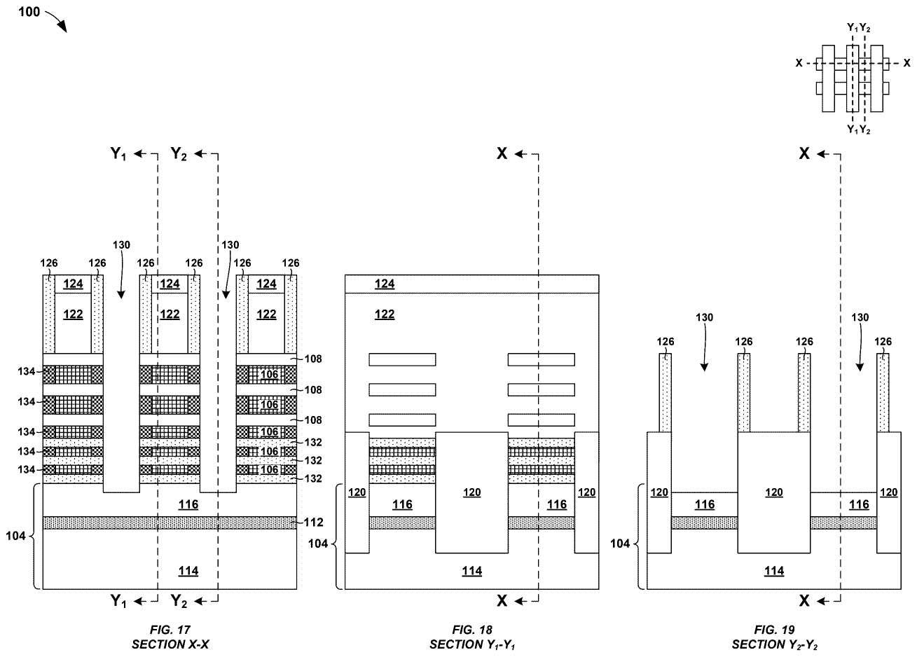

Referring now to FIGS. 17, 18, and 19, the structure 100 is shown after forming inner spacers 134 according to an embodiment of the invention. FIG. 17 depicts a cross-sectional view of the structure 100 taken along line X-X, FIG. 18 depicts a cross-sectional view of the structure 100 taken along line Y₁-Y₁, and FIG. 19 depicts a cross-sectional view of the structure 100 taken along line Y₂-Y₂.

Finally, the first sacrificial nanosheets 106 are laterally recessed to make room for the inner spacers 134. In one or more embodiments, the first sacrificial nanosheets 106 are laterally recessed using a hydrogen chloride (HCl) gas isotropic etch process, which etches silicon germanium without attacking silicon. In other embodiments, the first sacrificial nanosheets 106 are laterally recessed using a ClF3 etch process. Cavities (not shown) are formed by spaces that were occupied by the removed portions of the first sacrificial nanosheets 106.

The inner spacers 134 are formed by first conformally depositing a conformal spacer material over the structure 100 to fill the cavities created by laterally recessing the first sacrificial nanosheets 106. The conformal spacer material is then isotropically etched to remove all portions except those remaining in the cavities and forming the inner spacers 134. In one or more embodiments, the inner spacers 134 are made from a nitride containing material, for example silicon nitride (SiN). Although the inner spacers 134 are commonly made from a nitride containing material, they can be formed from any material which offers selectivity for subsequent device fabrication operations. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 134 can be selected based on a selectivity of subsequent device fabrication operations for the selected material being below a predetermined threshold.

The inner spacers 134 are positioned such that subsequent etching processes used to remove the first sacrificial nanosheets 106 during device fabrication do not also attack subsequently formed source drain regions.

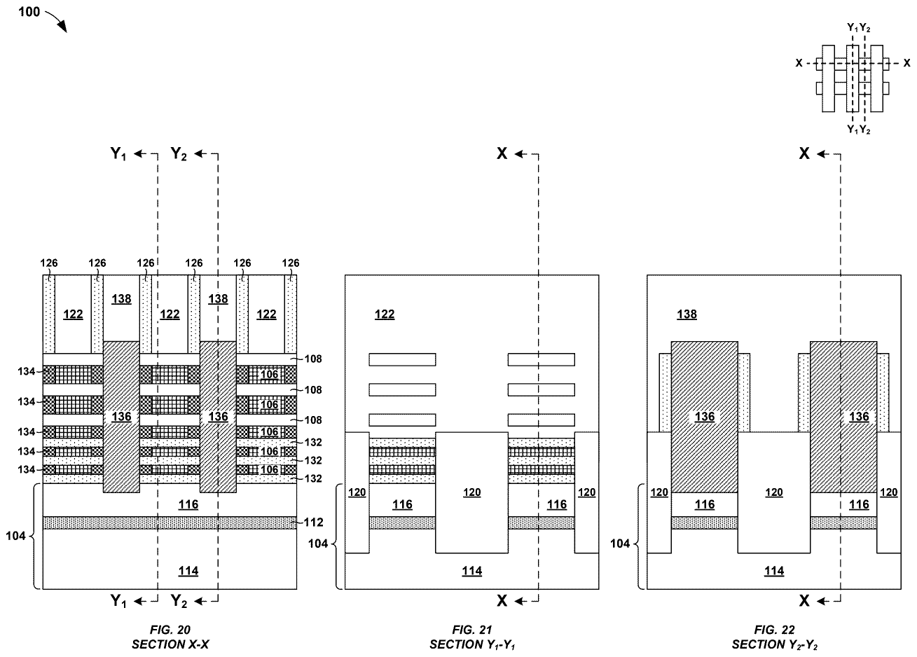

Referring now to FIGS. 20, 21, and 22, the structure 100 is shown after source drain regions 136 and a dielectric layer 138 according to an embodiment of the invention. FIG. 20 depicts a cross-sectional view of the structure 100 taken along line X-X, FIG. 21 depicts a cross-sectional view of the structure 100 taken along line Y₁-Y₁, and FIG. 22 depicts a cross-sectional view of the structure 100 taken along line Y₂-Y₂.

Next, the source drain regions 136 are formed using an epitaxial layer growth process on the exposed ends of the channel nanosheets 108 according to known techniques. Typically, in-situ doping is used to dope the source drain regions 136, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, at least some of the source drain regions 136 are of a first-type, for example, P-type, and at least some of the source drain regions 136 are of a second-type, for example, N-type.

Next, the dielectric layer 138 is blanket deposited an interlayer dielectric material over the structure 100 according to known techniques. Specifically, the dielectric layer 138 is formed on the source drain regions 136, as illustrated in FIG. 22, and substantially fills the remaining space between the sidewall spacers 126, as illustrated in FIG. 20.

The dielectric layer 138 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 138. Using a self-planarizing dielectric material as the dielectric layer 138 can avoid the need to perform a subsequent planarizing step.

After the dielectric layer 138 is formed, the backside of the structure 100 is polished according to known techniques, such as, for example, chemical mechanical polishing techniques. Specifically, the dielectric layer 138, the sidewall spacers 126, and the individual gate hard masks 124 are polished until the individual gate hard masks 124 are removed and topmost surfaces of the sacrificial gates 122 are exposed, as illustrated.

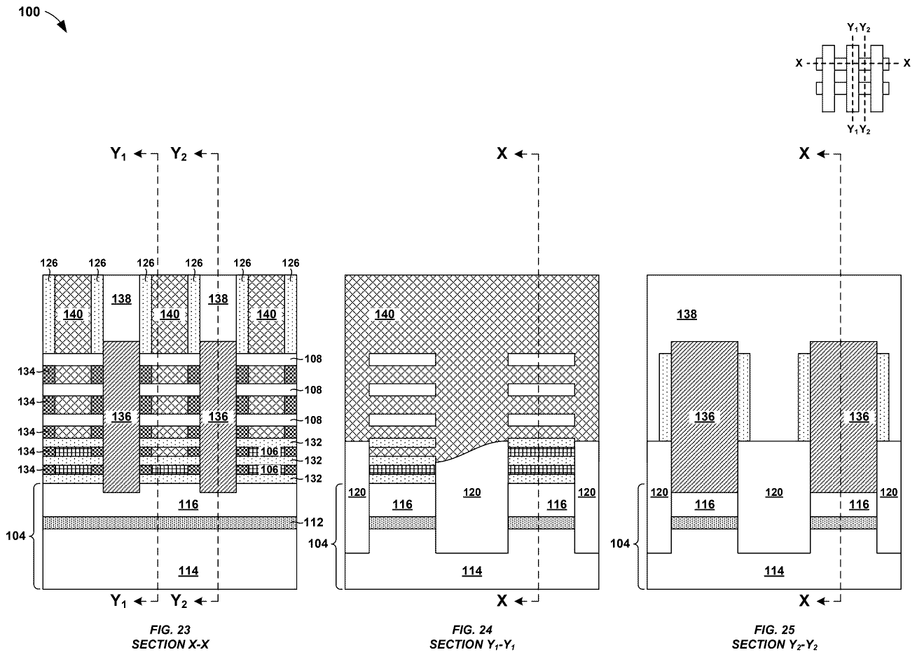

Referring now to FIGS. 23, 24, and 25, the structure 100 is shown after selectively removing the sacrificial gates 122 and the first sacrificial nanosheets 106, and forming gate structures 140 according to an embodiment of the invention. FIG. 23 depicts a cross-sectional view of the structure 100 taken along line X-X, FIG. 24 depicts a cross-sectional view of the structure 100 taken along line Y₁-Y₁, and FIG. 25 depicts a cross-sectional view of the structure 100 taken along line Y₂-Y₂.

First, the sacrificial gates 122 are selectively removed according to known techniques. Specifically, the sacrificial gates 122 are etched and removed selective to the gate spacers 126 and the individual nanosheet stacks 128 according to known techniques.

In some embodiments, portions of the STI regions 120 are etched or recessed during removal of the sacrificial gates 122. Alternatively, in other embodiments, portions of the STI regions 120 are etched or recessed subsequent to the removal of the sacrificial gates 122 using an additional removal or etching technique. It is noted, according to an embodiment, etching or recessing of the STI regions 120 is not uniform across the structure 100, as best illustrated in FIG. 24. Such non-uniformity is expected when removing the sacrificial gates 122 to reveal the channel nanosheets 108.

Next, the first sacrificial nanosheets 106 are etched and removed selective to the channel nanosheets 108 and the inner spacers 134 according to known techniques. Doing so is made possible by the different concentrations of germanium. In this case, the layers with germanium are removed selective to layers without germanium.

In regions where the STI regions 120 are recessed, additional layers of the first sacrificial nanosheets 106 arranged between two of the dielectric nanosheet layers 132 are also removed. In other regions, where the STI regions 120 are not recessed, all of the first sacrificial nanosheets 106 arranged between the dielectric nanosheet layers 132 will remain.

Next, the gate structures 140, include a gate dielectric and a work function metal, are formed according to known techniques. First, the gate dielectric (not shown) is conformally deposited directly on exposed surfaces of the structure 100 within the gate cavities or openings and spaces left by removing the sacrificial gates 122 and the first sacrificial nanosheets 106 according to known techniques. For example, the gate dielectric is conformally deposited on exposed surfaces of the channel nanosheets 108 and the inner spacers 134.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, the work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, a gate metal or a contact metal, is deposited directly on the work function metal, and fills the gate cavities. The gate metal may include any suitable conductive material, such as, for example, copper, ruthenium, aluminum, tungsten, cobalt, or alloys thereof. After deposition, excess gate metal can be polished using known techniques.

It is noted, when portions of the STI regions 120 are etched or recessed, any space between the dielectric nanosheet layers 132 is substantially filled by the gate structure 140, as best illustrated in FIG. 24. For example, according to an embodiment, one of the first sacrificial nanosheets 106 in the individual nanosheet stack 128 depicted on the left of FIG. 24 is removed and replaced by the gate structure 140, and none of the first sacrificial nanosheets 106 in the individual nanosheet stack 128 depicted on the right of FIG. 24 are removed or replaced by the gate structure 140. In yet another embodiment, none of the first sacrificial nanosheets 106 are removed and replaced by the gate structure 140. In yet another embodiment, some of the first sacrificial nanosheets 106 are removed and replaced by the gate structure 140 in all individual nanosheet stacks 128 across the structure 100.

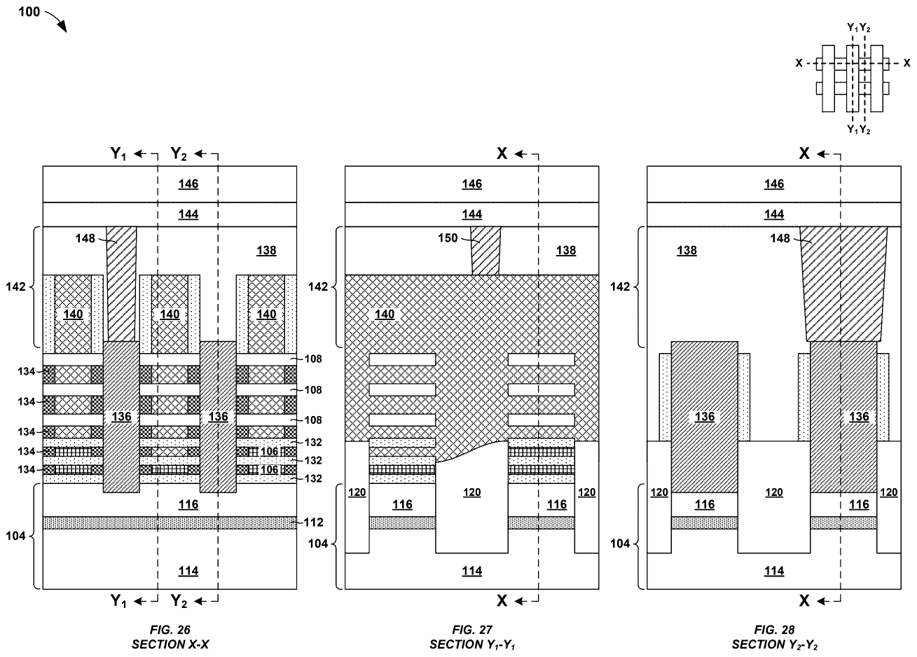

Referring now to FIGS. 26, 27, and 28, the structure 100 is shown after forming middle-of-line 142, back-end-of-line 144, and attaching a carrier wafer 146 according to an embodiment of the invention. FIG. 26 depicts a cross-sectional view of the structure 100 taken along line X-X, FIG. 27 depicts a cross-sectional view of the structure 100 taken along line Y₁-Y₁, and FIG. 28 depicts a cross-sectional view of the structure 100 taken along line Y₂-Y₂.

The middle-of-line 142 includes source drain contacts 148 and gate contacts 150 which may be generally referred to as middle-of-line contacts. The source drain contacts 148 and the gate contacts 150 are formed according to known techniques. First, additional interlayer dielectric material is deposited according to known techniques. The dielectric layer 138 illustrated in the figures includes the additional interlayer dielectric material. Next, portions of the dielectric layer 138 are removed to expose the source drain regions 136. The openings are then filled with a conductive material to form the middle-of-line contacts according to known techniques. The middle-of-line contacts include any suitable conductive material, such as, for example, copper, ruthenium, aluminum, tungsten, cobalt, or alloys thereof. In some embodiments, a metal silicide is formed at the bottom of the contact trenches prior to filling them with the conductive material.

The back-end-of-line 144 may include vias and metal lines which may be generally referred to as back-end-of-line interconnects. The vias and the metal lines are formed according to known techniques.

Finally, the carrier wafer 146 is secured to a top of the structure 100 according to an embodiment of the invention. The carrier wafer 146 is attached, or removably secured, to the back-end-of-line 144. In general, and not depicted, the carrier wafer 146 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 146 according to known techniques.

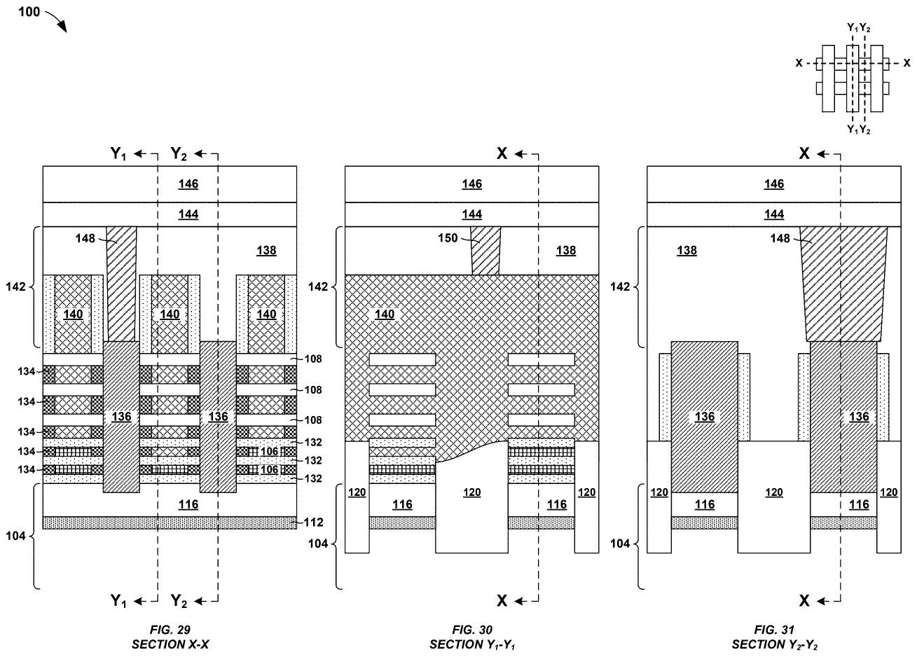

Referring now to FIGS. 29, 30, and 31, the structure 100 is shown after flipping the assembly and recessing the substrate 104 according to an embodiment of the invention. FIG. 29 depicts a cross-sectional view of the structure 100 taken along line X-X, FIG. 30 depicts a cross-sectional view of the structure 100 taken along line Y₁-Y₁, and FIG. 31 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 104 is recessed according to known techniques. Specifically, the base substrate 114 is recessed or completely removed to expose the etch stop layer 112, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

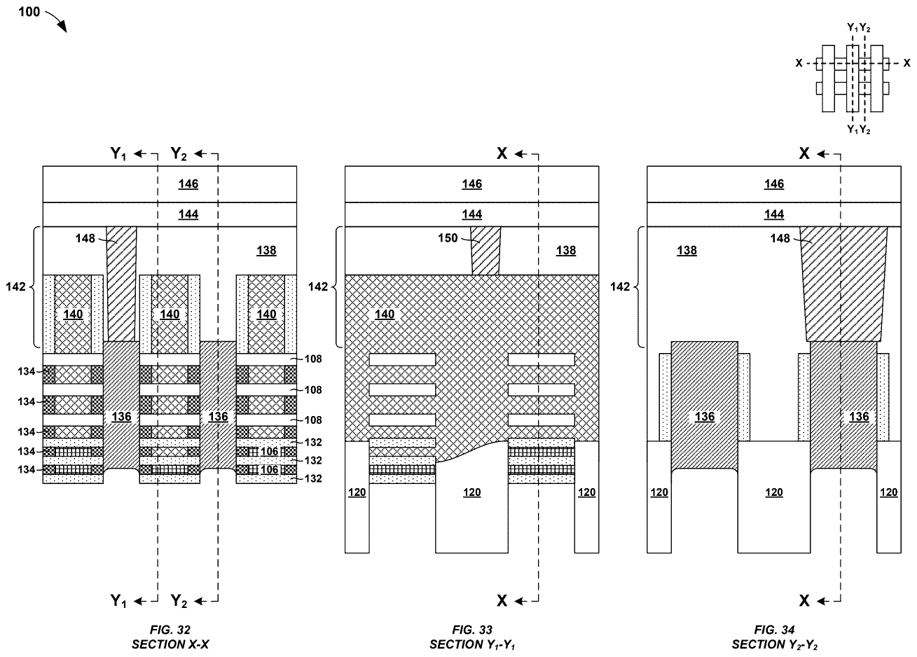

Referring now to FIGS. 32, 33, and 34, the structure 100 is shown after removing and recessing remaining portions of the substrate 104 according to an embodiment of the invention. FIG. 32 depicts a cross-sectional view of the structure 100 taken along line X-X, FIG. 33 depicts a cross-sectional view of the structure 100 taken along line Y₁-Y₁, and FIG. 34 depicts a cross-sectional view of the structure 100 taken along line Y₂-Y₂.

First, the etch stop layer 112 is selectively removed and the top semiconductor layer 116 is recessed according to known techniques. Specifically, the etch stop layer 112 is removed selective to the top semiconductor layer 116 and the top semiconductor layer 116 is removed selective to the dielectric nanosheet layers 132, the source drain regions 136, and the STI regions 120, as illustrated. According to an embodiment, the source drain regions 136 may experience some erosion or etch back during recessing the top semiconductor layer 116, as illustrated. It is noted, even when the source drain regions 136 experience some erosion, the dielectric nanosheet layers 132 provide an adequate buffer and effectively prevent the channel nanosheets 108 and the gate structures 140 from also becoming exposed.

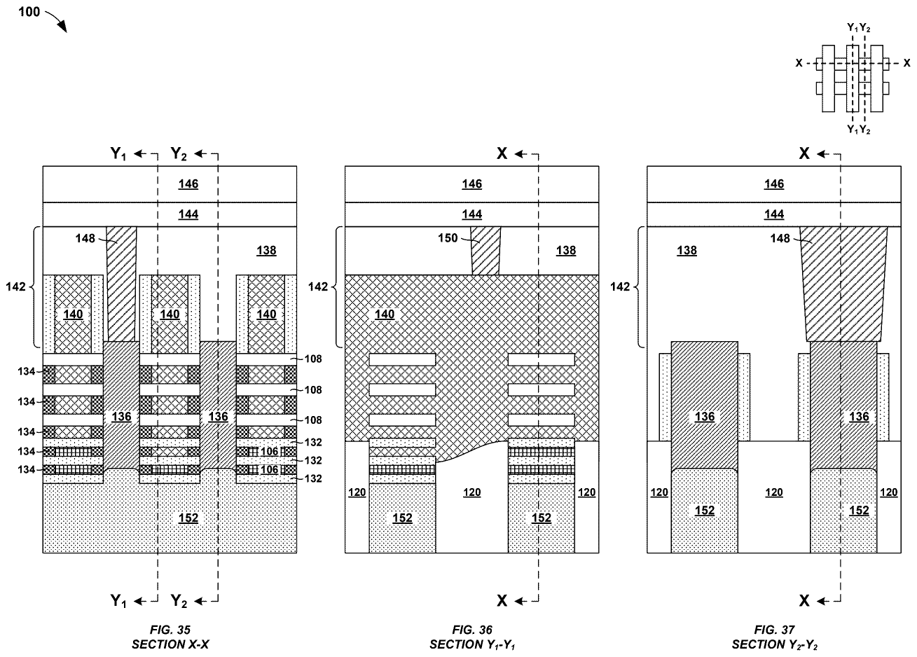

Referring now to FIGS. 35, 36, and 37, the structure 100 is shown after forming a backside dielectric layer 152 according to an embodiment of the invention. FIG. 35 depicts a cross-sectional view of the structure 100 taken along line X-X, FIG. 36 depicts a cross-sectional view of the structure 100 taken along line Y₁-Y₁, and FIG. 37 depicts a cross-sectional view of the structure 100 taken along line Y₂-Y₂.

The backside dielectric layer 152 is formed by blanket depositing an interlayer dielectric material over the backside of the structure 100 according to known techniques. Specifically, the backside dielectric layer 152 is formed on and covers exposed bottoms surfaces of the dielectric nanosheet layers 132, and the source drain regions 136, as illustrated. The backside dielectric layer 152 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 152. Using a self-planarizing dielectric material as the backside dielectric layer 152 can avoid the need to perform a subsequent planarizing step. In at least one embodiment, the backside dielectric layer 152 is an oxide and the dielectric nanosheet layers 132 are nitride.

After the backside dielectric layer 152 is formed, the backside of the structure 100 is polished according to known techniques, such as, for example, chemical mechanical polishing techniques. Specifically, polishing continues until bottommost surfaces of the backside dielectric layer 152 are flush, or substantially flush, with bottommost surfaces of the STI regions 120, as illustrated.

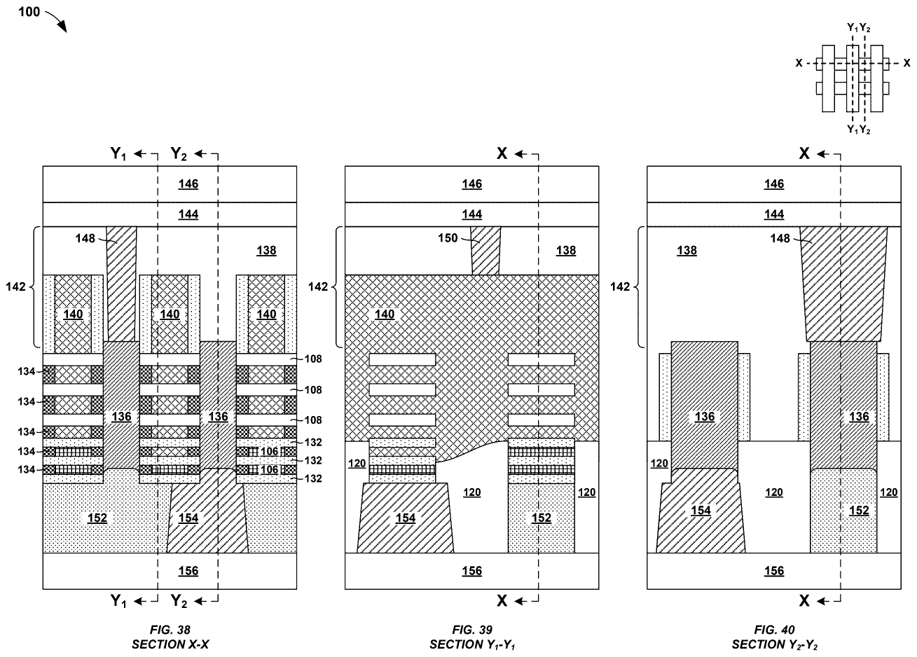

Referring now to FIGS. 38, 39, and 40, the structure 100 is shown after forming backside contact structures 154 and backside wiring layers 156 according to an embodiment of the invention. FIG. 38 depicts a cross-sectional view of the structure 100 taken along line X-X, FIG. 39 depicts a cross-sectional view of the structure 100 taken along line Y₁-Y₁, and FIG. 40 depicts a cross-sectional view of the structure 100 taken along line Y₂-Y₂.

First, a mask (not shown) is deposited and subsequently patterned to expose certain portions of the structure 100 according to known techniques. According to at least one embodiment, the mask can be an organic planarization layer (OPL) or a layer of material that is capable of being planarized or etched by known techniques. After depositing the mask, a dry etching technique is applied to pattern or recess the mask according to known techniques. The mask is patterned consistent with a size and a location of subsequently formed backside contact structures.

Exposed portions of the backside dielectric layer 152 are then selectively removed to form backside trenches (not shown) according to known techniques. Specifically, exposed portions of the backside dielectric layer 152 are removed using known etching techniques suitable to remove silicon-based dielectric materials selective to the mask. In an embodiment, the exposed portions of the backside dielectric layer 152 are removed using an anisotropic etch such as, for example, reactive ion etching (RIE).

Next, the backside contact trenches are filled with a conductive material to form the backside contact structures 154 according to known techniques. The backside contact structures 154 may include any suitable conductive material, such as, for example, copper, ruthenium, aluminum, tungsten, cobalt, or alloys thereof. Additionally, the backside contact structures 154 may alternatively be referred to as direct backside contacts.

After deposition, excess conductive material can be polished using known techniques until bottommost surfaces of the backside contact structures 154 are flush, or substantially flush, with bottommost surfaces of the backside dielectric layer 152, as illustrated. After polishing, bottommost surfaces of the backside contact structures 154 are substantially flat.

It is noted, because of the intentional addition of the dielectric nanosheet layers 132 to the bottom of the individual nanosheet stacks 128, the backside contact structures 154 are entirely below a bottommost surface of the gate structure. Further, the backside contact structures 154 are physically separated and isolated from the gate structure 140 by at least one of the dielectric nanosheet layers 132 and at least one of the first sacrificial nanosheets 106, as best illustrated in FIG. 38.

Finally, after forming the backside contact structures 154, the backside wiring layers 156 are subsequently formed according to known techniques. The backside wiring layers 156 typically include at least backside power rails and a backside power delivery network.

According to the embodiment illustrated in FIG. 38-40, the transistor structures represented by the structure 100 have some distinctive notable features. For instance, the source drain regions 136 extend toward a backside of the structure 100 below the channel nanosheets 108. Additionally, the backside contact structures 154 are arranged on the backside of the structure 100 and in direct contact with the source drain regions 136. Further, it is noted, the dielectric nanosheet layers 132 in combination with the remaining first sacrificial nanosheets 106 successfully prevent shorting between the backside contact structures 154 and the gate structures 140

It is noted, the dielectric nanosheet layers 132 are arranged directly beneath the channel nanosheets 108 and are physically separated by the first sacrificial nanosheets 106. Further, the backside contact structure 154 is entirely below a bottommost surface of a gate structure 140. As previously described above, a portion of the gate structure 140 may be arranged between at least two of the dielectric nanosheet layers 132. Moreover, a bottommost surface of the source drain regions 136 is above a bottommost surface of the dielectric nanosheet layers 132. In at least one embodiment, the backside dielectric layer 152 is an oxide and the dielectric nanosheet layers 132 are nitride.

With continued reference to FIG. 38-40, and according to an embodiment, the structure 100 includes a nanosheet stack comprising a series of channel nanosheets, dielectric nanosheet layers arranged directly beneath the series of channel nanosheets, and semiconductor layers between and physically separating the dielectric nanosheet layers from one another.

With continued reference to FIG. 38-40, and according to an embodiment, the structure further includes a backside contact structure, where the backside contact structure is entirely below a bottommost surface of a gate structure.

With continued reference to FIG. 38-40, and according to an embodiment, the structure further includes a gate structure, where a portion of the gate structure is arranged between at least two of the dielectric nanosheet layers.

With continued reference to FIG. 38-40, and according to an embodiment, the structure further includes a source drain region adjacent to the nanosheet stack, where a bottommost surface of the source drain region is above a bottommost surface of the dielectric nanosheet layers.

With continued reference to FIG. 38-40, and according to an embodiment, the structure further includes inner spacers, where at least one of the inner spacers is arranged between and physically separates the semiconductor layers from an adjacent source drain region.

With continued reference to FIG. 38-40, and according to an embodiment, the structure further includes a backside dielectric layer is an oxide, where the dielectric nanosheet layers are nitride.

With continued reference to FIG. 38-40, and according to an embodiment, the semiconductor layers are made from silicon germanium.

With continued reference to FIG. 38-40, and according to an embodiment, the structure 100 includes a nanosheet stack comprising a series of channel nanosheets, at least two dielectric nanosheet layers arranged directly beneath the series of channel nanosheets, and at least one semiconductor layer between and physically separating the at least two dielectric nanosheet layers from one another.

With continued reference to FIG. 38-40, and according to an embodiment, the structure 100 includes a first nanosheet stack comprising a first series of channel nanosheets, at least three first dielectric nanosheet layers arranged directly beneath the first series of channel nanosheets, at least one first semiconductor layer between and physically separating two of the at least three first dielectric nanosheet layers from one another, and a gate structure between and physically separating two of the at least three first dielectric nanosheet layers from one another.

Various examples may possibly be described by one or more of the following features in the following numbered clauses:

Clause 1: A semiconductor structure including a nanosheet stack comprising a series of channel nanosheets, dielectric nanosheet layers arranged directly beneath the series of channel nanosheets, and semiconductor layers between and physically separating the dielectric nanosheet layers from one another.

Clause 2: The semiconductor structure according to clause 1, further including a backside contact structure, where the backside contact structure is entirely below a bottommost surface of a gate structure.

Clause 3: The semiconductor structure according to clauses 1 and 2, further including a gate structure, where a portion of the gate structure is arranged between at least two of the dielectric nanosheet layers.

Clause 4: The semiconductor structure according to clauses 1, 2, and 3, further including a source drain region adjacent to the nanosheet stack, where a bottommost surface of the source drain region is above a bottommost surface of the dielectric nanosheet layers.

Clause 5: The semiconductor structure according to clauses 1, 2, 3, and 4, further including inner spacers, where at least one of the inner spacers is arranged between and physically separates the semiconductor layers from an adjacent source drain region.

Clause 6: The semiconductor structure according to clauses 1, 2, 3, 4, and 5, further including a backside dielectric layer is an oxide, where the dielectric nanosheet layers are nitride.

Clause 7: The semiconductor structure according to clauses 1, 2, 3, 4, 5, and 6, where the semiconductor layers are made from silicon germanium.

Clause 8: A semiconductor structure including a nanosheet stack comprising a series of channel nanosheets, at least two dielectric nanosheet layers arranged directly beneath the series of channel nanosheets, and at least one semiconductor layer between and physically separating the at least two dielectric nanosheet layers from one another.

Clause 9: The semiconductor structure according to clause 8, further including a backside contact structure, where the backside contact structure is entirely below a bottommost surface of a gate structure.

Clause 10: The semiconductor structure according to clauses 8 and 9, further including a gate structure, where a portion of the gate structure is arranged between at least two of the at least two dielectric nanosheet layers.

Clause 11: The semiconductor structure according to clauses 8, 9, and 10, further including a source drain region adjacent to the nanosheet stack, where a bottommost surface of the source drain region is above a bottommost surface of the at least two dielectric nanosheet layers.

Clause 12: The semiconductor structure according to clauses 8, 9, 10, and 11, further including inner spacers, where at least one of the inner spacers is arranged between and physically separates the at least one semiconductor layer from an adjacent source drain region.

Clause 13: The semiconductor structure according to clauses 8, 9, 10, 11, and 12, further including a backside dielectric layer is an oxide, where the at least two dielectric nanosheet layers are nitride.

Clause 14: The semiconductor structure according to clauses 8, 9, 10, 11, 12, and 13, where the at least one semiconductor layer are made from silicon germanium.

Clause 15: A semiconductor structure including a first nanosheet stack comprising a first series of channel nanosheets, at least three first dielectric nanosheet layers arranged directly beneath the first series of channel nanosheets, at least one first semiconductor layer between and physically separating two of the at least three first dielectric nanosheet layers from one another, and a gate structure between and physically separating two of the at least three first dielectric nanosheet layers from one another.

Clause 16: The semiconductor structure according to clause 15, further including a second nanosheet stack comprising a second series of channel nanosheets, at least three second dielectric nanosheet layers arranged directly beneath the second series of channel nanosheets, and at least two second semiconductor layers between and physically separating each of the at least three second dielectric nanosheet layers from one another.

Clause 17: The semiconductor structure according to clauses 15 and 16, further including a backside contact structure, where the backside contact structure is entirely below a bottommost surface of a gate structure.

Clause 18: The semiconductor structure according to clauses 15, 16, and 17, further including a source drain region adjacent to the first nanosheet stack, where a bottommost surface of the source drain region is above a bottommost surface of the at least three first dielectric nanosheet layers.

Clause 19: The semiconductor structure according to clauses 15, 16, 17, and 18, further including inner spacers, where at least one of the inner spacers is arranged between and physically separates the at least one first semiconductor layer from an adjacent source drain region.

Clause 20: The semiconductor structure according to clauses 15, 16, 17, 18, and 19, further including a backside dielectric layer is an oxide, where the at least three first dielectric nanosheet layers are nitride.

What is claimed is:

1. A semiconductor structure comprising:
a nanosheet stack comprising a series of channel nanosheets;
dielectric nanosheet layers arranged directly beneath the series of channel nanosheets; and
semiconductor layers between and physically separating the dielectric nanosheet layers from one another.

2. The semiconductor structure according to claim 1, further comprising:
a backside contact structure, wherein the backside contact structure is entirely below a bottommost surface of a gate structure.

3. The semiconductor structure according to claim 1, further comprising:
a gate structure, wherein a portion of the gate structure is arranged between at least two of the dielectric nanosheet layers.

4. The semiconductor structure according to claim 1, further comprising:
a source drain region adjacent to the nanosheet stack, wherein a bottommost surface of the source drain region is above a bottommost surface of the dielectric nanosheet layers.

5. The semiconductor structure according to claim 1, further comprising:
inner spacers, wherein at least one of the inner spacers is arranged between and physically separates the semiconductor layers from an adjacent source drain region.

6. The semiconductor structure according to claim 1, further comprising:
a backside dielectric layer is an oxide, wherein the dielectric nanosheet layers are nitride.

7. The semiconductor structure according to claim 1, wherein the semiconductor layers are made from silicon germanium.

8. A semiconductor structure comprising:
a nanosheet stack comprising a series of channel nanosheets;
at least two dielectric nanosheet layers arranged directly beneath the series of channel nanosheets; and
at least one semiconductor layer between and physically separating the at least two dielectric nanosheet layers from one another.

9. The semiconductor structure according to claim 8, further comprising:
a backside contact structure, wherein the backside contact structure is entirely below a bottommost surface of a gate structure.

10. The semiconductor structure according to claim 8, further comprising;
a gate structure, wherein a portion of the gate structure is arranged between at least two of the at least two dielectric nanosheet layers.

11. The semiconductor structure according to claim 8, further comprising:
a source drain region adjacent to the nanosheet stack, wherein a bottommost surface of the source drain region is above a bottommost surface of the at least two dielectric nanosheet layers.

12. The semiconductor structure according to claim 8, further comprising:
inner spacers, wherein at least one of the inner spacers is arranged between and physically separates the at least one semiconductor layer from an adjacent source drain region.

13. The semiconductor structure according to claim 8, further comprising:
a backside dielectric layer is an oxide, wherein the at least two dielectric nanosheet layers are nitride.

14. The semiconductor structure according to claim 8, wherein the at least one semiconductor layer are made from silicon germanium.

15. A semiconductor structure comprising:
a first nanosheet stack comprising a first series of channel nanosheets;
at least three first dielectric nanosheet layers arranged directly beneath the first series of channel nanosheets;
at least one first semiconductor layer between and physically separating two of the at least three first dielectric nanosheet layers from one another; and
a gate structure between and physically separating two of the at least three first dielectric nanosheet layers from one another.

16. The semiconductor structure according to claim 15, further comprising:
a second nanosheet stack comprising a second series of channel nanosheets;
at least three second dielectric nanosheet layers arranged directly beneath the second series of channel nanosheets; and
at least two second semiconductor layers between and physically separating each of the at least three second dielectric nanosheet layers from one another.

17. The semiconductor structure according to claim 15, further comprising:
a backside contact structure, wherein the backside contact structure is entirely below a bottommost surface of a gate structure.

18. The semiconductor structure according to claim 15, further comprising:
a source drain region adjacent to the first nanosheet stack, wherein a bottommost surface of the source drain region is above a bottommost surface of the at least three first dielectric nanosheet layers.

19. The semiconductor structure according to claim 15, further comprising:
inner spacers, wherein at least one of the inner spacers is arranged between and physically separates the at least one first semiconductor layer from an adjacent source drain region.

20. The semiconductor structure according to claim 15, further comprising:
a backside dielectric layer is an oxide, wherein the at least three first dielectric nanosheet layers are nitride.
